(19) United States
(12) Patent Application Publication
(10) Pub. No.: US 2019/0382618 A1
(43) Pub. Date: Dec. 19, 2019

(54) HYDROXYL FULLERENE DISPERSION, METHOD OF PREPARING THE SAME, POLISHING SLURRY INCLUDING THE SAME, AND METHOD OF MANUFACTURING A SEMICONDUCTOR DEVICE

(71) Applicant: SAMSUNG ELECTRONICS CO., LTD., Suwon-si (KR)

(72) Inventors: Kenji TAKAI, Hwaseong-si (KR); Sang Eui LEE, Hwaseong-si (KR); Hiroshi MIYAZAKI, Hwaseong-si (KR)

(21) Appl. No.: 16/421,633

(22) Filed: May 24, 2019

(30) Foreign Application Priority Data
Jun. 19, 2018 (KR) 10-2018-0070201

(51) Int. Cl. C09G 1/02; C01B 32/156; B24B 37/04; H01L 21/321; H01L 21/768

(52) U.S. Cl. CPC C09G 1/02; C01B 32/156; H01L 21/7684; H01L 21/3212; B24B 37/044

(57) ABSTRACT

A method of preparing a hydroxyl fullerene dispersion including mixing fullerene, a dispersing agent, a first oxidizing agent, or a combination thereof, in water, crushing the fullerene to obtain pulverized fullerene and oxidizing the pulverized fullerene to obtain hydroxyl fullerene represented by Cₓ(OH)_{y}, wherein, x is 60, 70, 74, 76 or 78 and y is 12 to 44, and to prepare the hydroxyl fullerene dispersion.

### CROSS-REFERENCE TO RELATED APPLICATION

This application claims priority to and the benefit of Korean Patent Application No. 10-2018-0070201 filed in the Korean Intellectual Property Office on Jun. 19, 2018, and all the benefits accruing therefrom under 35 U.S.C. § 119, the entire contents of which are incorporated herein by reference.

### BACKGROUND

### 1. Field

A hydroxyl fullerene dispersion and a method of preparing the same, a polishing slurry including the hydroxyl fullerene dispersion, and a method of manufacturing a semiconductor device using the polishing slurry are disclosed.

### 2. Description of the Related Art

A semiconductor device is generally required to have a structure with a planar surface during the manufacturing process, and such a structure may be obtained by a polishing process. An example of the polishing process is chemical mechanical polishing (CMP). Chemical mechanical polishing is a process including providing a polishing slurry between a substrate to be polished and a polishing pad, contacting the semiconductor substrate to the polishing pad, and rotating the same to planarize a surface of the substrate by pressing and rotating.

Recently, high-performance and highly-integrated semiconductor devices having a structure with a fine pitch of less than or equal to about 10 nm have been used for certain applications, resulting in a need for polishing slurries capable of providing the fine pitch structure.

### SUMMARY

An embodiment provides a method of preparing hydroxyl fullerene dispersion that may be used as a polishing slurry appropriate for a structure of a fine pitch.

An embodiment provides the hydroxyl fullerene dispersion.

An embodiment provides a polishing slurry including the hydroxyl fullerene dispersion.

An embodiment provides a method of manufacturing a semiconductor device using the polishing slurry.

According to an embodiment, a method of preparing hydroxyl fullerene dispersion includes combining fullerene, a dispersing agent, a first oxidizing agent, or a combination thereof, and water to provide a mixture, crushing the mixture to obtain pulverized fullerene, and oxidizing the pulverized fullerene to obtain hydroxyl fullerene represented by Cₓ(OH)_{y} wherein, x is 60, 70, 74, 76 or 78 and y is 12 to 44 and to prepare the hydroxyl fullerene dispersion.

The oxidizing of the pulverized fullerene may include adding a second oxidizing agent to the pulverized fullerene to provide a second mixture comprising the second oxidizing agent and heat-treating the second mixture.

The first oxidizing agent and the second oxidizing agent may be the same or different materials capable of producing a hydroxide radical.

The first oxidizing agent and the second oxidizing agent may independently include hydrogen peroxide, hydrogen peroxide water, ozone, or a combination thereof.

The heat-treating may be performed at about 50° C. to about 120° C.

The dispersing agent may include a water-soluble monomer, a water-soluble oligomer, a water-soluble polymer, a metal salt, or a combination thereof.

The crushing of the fullerene may be performed using a beads mill, a high-speed rotation agitator, a vacuum emulsion agitator, a colloid mill, a roll mill, a high-pressure spraying disperser, or an ultrasonic wave disperser.

The crushing of the fullerene may be performed for about 1 hour to about 100 hours.

The dispersing agent may be present in an amount of greater than 0 weight percent (wt %) to about 10 wt % based on a total amount of the mixture and the first oxidizing agent may be present in an amount of greater than 0 wt % to about 30 wt % based on a total amount of the mixture.

The pulverized fullerene may include a plurality of pulverized fullerene particles and an average particle diameter of the plurality of pulverized fullerene particles may be less than or equal to about 100 nanometers (nm).

An average particle diameter of the plurality of hydroxyl fullerene particles may be less than or equal to about 10 nm.

The manufacturing method may not use an organic solvent.

The hydroxyl fullerene may be represented by Cₓ(OH)_{y} (wherein, x is 60, 70, 74, 76, or 78 and y is 24 to 44).

According to an embodiment, hydroxyl fullerene dispersion obtained by the method is provided.

According to an embodiment, a polishing slurry including the hydroxyl fullerene dispersion is provided.

According to an embodiment, the polishing slurry includes a hydroxyl fullerene represented by Cₓ(OH)_{y} (wherein, x is 60, 70, 74, 76, or 78 and y is 12 to 44) and the plurality of hydroxyl fullerene particles may have an average particle diameter of less than or equal to about 10 nm and water.

The polishing slurry may be more transparent by inspection by the naked eye than water and fullerene (Cₓ, wherein x is 60, 70, 74, 76, or 78).

The hydroxyl fullerene may be represented by Cₓ(OH)_{y} (wherein, x is 60, 70, 74, 76, or 78 and y is 24 to 44).

The polishing slurry may further include a chelating agent, a surfactant, or a combination thereof.

According to an embodiment, a method of manufacturing a semiconductor device using the polishing slurry is provided.

A method of preparing hydroxyl fullerene dispersion is provided, so as to effectively and inexpensively obtain a dispersion including fine hydroxyl fullerene particles having a size of less than or equal to about 10 nm. In addition, the hydroxyl fullerene dispersion may be substituted for a silica abrasive in a polishing slurry to reduce structure damage and shape deformation that may be caused by polishing and also to improve polishing speed.

### BRIEF DESCRIPTION OF THE DRAWINGS

FIG. 1 is a liquid chromatography-mass spectrometry (LCMS) graph of a hydroxyl fullerene included in dispersion obtained from Preparation Example 1,

FIG. 2 is a LCMS graph of a hydroxyl fullerene included in dispersion obtained from Comparative Preparation Example 1,

FIG. 3 is an image of fullerene (C60) dispersion before initiating beads mill in Preparation Example 1,

FIG. 4A is an image of the dispersion directly after beads mill in Preparation Example 1, FIG. 4B is an image of the dispersion after performing an oxidation process for about 4 days, and FIG. 4C is an image of the dispersion after performing an oxidation process for 8 days, and

FIGS. 5 to 8 are cross-sectional views sequentially showing a method of manufacturing a semiconductor device according to an embodiment.

### DETAILED DESCRIPTION

Example embodiments will hereinafter be described in detail, and may be easily performed by those who have common knowledge in the related art. However, this disclosure may be embodied in many different forms and is not to be construed as limited to the exemplary embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that, although the terms “first,” “second,” “third” etc. may be used herein to describe various elements and/or components, these elements and/or components should not be limited by these terms. These terms are only used to distinguish one element or component from another element or component. Thus, “a first element” or “component” discussed below could be termed a second element or component without departing from the teachings herein.

Hereinafter, a method of preparing a hydroxyl fullerene dispersion according to an embodiment is described.

A method of preparing a hydroxyl fullerene dispersion according to an embodiment may be a one-pot process without a solvent exchange process and includes combining, e.g., mixing fullerene, together with a dispersing agent, a first oxidizing agent, or a combination thereof in water to provide a fullerene mixture, crushing the fullerene mixture to obtain pulverized fullerene in the mixture, and oxidizing the pulverized fullerene.

The fullerene, together with the dispersing agent, the first oxidizing agent, or the combination thereof may be mixed in water and prepared as a mixture.

The fullerene may be for example C60, C70, C74, C76, C78, or a combination thereof, but is not limited thereto. The fullerene may be generally hydrophobic and may not be dispersed in water and may be present as a fullerene agglomerate in water. The fullerene agglomerate may have a particle diameter of greater than or equal to hundreds of nanometers and may be effectively dispersed in water through, e.g., by, a crushing process which will be described later.

The fullerene may be included in an amount of about 0.1 wt % to about 50 wt %, and within the range, about 0.1 wt % to about 30 wt %, for example about 0.1 wt % to about 20 wt %, about 0.1 wt % to about 10 wt %, or about 0.1 wt % to about 6 wt % based on a total amount of the mixture.

The dispersing agent may accelerate dispersion of the fullerene agglomerate in water, and the dispersing agent may include, for example, a water-soluble monomer, a water-soluble oligomer, a water-soluble polymer, a metal salt, or a combination thereof. The water-soluble polymer may have a weight average molecular weight of, for example, less than or equal to about 10,000 grams per mole (g/mol), less than or equal to about 5,000 g/mol, or less than or equal to about 3,000 g/mol. The metal salt may be for example a copper salt, a nickel salt, a cobalt salt, a manganese salt, a tantalum salt, a ruthenium salt, or a combination thereof. The dispersing agent may for example include a poly(meth)acrylic acid, poly(meth)acryl-maleic acid, polyacrylonitrile-co-butadiene-acrylic acid, carboxylic acid, sulfonic ester, sulfonic acid, phosphoric ester, ethylene glycol, polyethylene glycol, imine, ethylene imine, polyethylene imine, cellulose, diol, metal acetate such as copper acetate, a salt thereof, or a combination thereof, but is not limited thereto.

The dispersing agent may be included in an amount of greater than 0 wt % to about 10 wt %, and within the range, for example about 0.01 wt % to about 10 wt %, about 0.01 wt % to about 5 wt %, about 0.01 wt % to about 3 wt %, or about 0.01 wt % to about 2 wt % based on a total amount of the mixture.

The first oxidizing agent may be a material capable of producing a hydroxide radical, for example hydrogen peroxide, hydrogen peroxide water, ozone, or a combination thereof.

The first oxidizing agent may be included in an amount of greater than 0 wt % to about 30 wt %, the range for example about 0.01 wt % to about 30 wt %, about 0.01 wt % to about 25 wt %, about 0.01 wt % to about 20 wt %, about 0.01 wt % to about 15 wt %, or about 0.01 wt % to about 10 wt % based on a total amount of the mixture.

One or more of each of the dispersing agent and the first oxidizing agent may be included.

For example, the fullerene and the dispersing agent may be mixed in water.

For example, the fullerene and the first oxidizing agent may be mixed in water.

For example, the fullerene, the dispersing agent, and the first oxidizing agent may be mixed in water.

The dispersing agent, the first oxidizing agent, or a combination thereof may be bound to the surface of the fullerene physically or chemically.

The water may be for example distilled water, deionized water, or a combination thereof.

Subsequently, the fullerene in the mixture is crushed. The crushing may include dispersing the agglomerated particles and pulverizing the dispersed particles.

The crushing may be for example may be performed using a beads mill, a high-speed rotation agitator, a vacuum emulsion agitator, a colloid mill, a roll mill, a high-pressure spraying disperser, or an ultrasonic wave disperser, but is not limited thereto.

Beads milling, e.g., grinding using a beads mill, is a method of grinding particles while encouraging collisions between a plurality of beads and particles (e.g., fullerene agglomerates). For example, the mixture is added into the mill and filled with beads, then the mill is vibrated, rotated, or a combination thereof to grind the agglomerated fullerene by collision force to disperse the fullerene in water. The shape of beads is not particularly limited, but may be, for example, circle, sheet-shape, polygon, or a combination thereof. Beads may be made of, for example, metal, semi-metal, non-metal, oxide, or a combination thereof, or may be made of, for example, glass, alumina, zircon, zirconia, steel, or a combination thereof, or may include, for example, SiO₂, Na₂O, MgO, Al₂O₃, CaO, B₂O₃, K₂O, ZrO₂, Y₂O₃, Fe, Cr, Si, Mn, P, S, or a combination thereof. A size of beads may range from about 10 micrometers (μm) to about 20 mm, from about 20 μm to about 15 mm, or from about 30 μm to about 10 mm, but is not limited thereto. The beads may be included in the mill in an amount ranging from about 10 volume percent (vol %) to about 95 vol %, from about 10 vol % to about 85 vol %, or from about 20 vol % to about 80 vol % of the mill. Beads milling may be performed at about 20 to about 80° C.

A high-speed rotation agitator may be an agitator capable of rotating at a speed of, for example, greater than or equal to about 6,000 revolutions per minute (r/min), or about 6,000 to about 30,000 r/min. The high-speed rotation agitator may be, for example, a compressing-type or a shearing-type, but is not limited thereto.

A high-speed rotation agitator may be, for example, a high-speed rotation shearing-type agitator, and the high-speed rotation shearing-type agitator may crush particles with a strong turbulence, impact generated by a rotating impeller at a high speed, or a combination thereof. For example, the impeller may include a turbine impeller, a paddle impeller, a slope paddle impeller, a backward impeller, an anchor impeller, or a combination thereof, but is not limited thereto. For example, the turbine impeller may have a stator (exterior wall). In this case, the turbine impeller may provide a fine dispersion by a strong shear force, impact, turbulence, or a combination thereof generated in a gap between the stator and the turbine. In addition, the agitator may use an impeller that moves up and down along an outer circumference of a disc called a disperser blade that may be shaped with saw teeth. Alternatively, the agitator may use an ultra-mixer impeller which may be a system that includes sucking up the dispersion in the mixer through a rotation hood and a suction force caused by a cavitation, and then blowing the same out from the side.

A vacuum emulsion agitator may agitate while removing foam which may cause particle agglomeration.

A colloid mill or a roll mill may have a system capable of supplying dispersion onto two adjacent surfaces that are rotated to provide liquid with a shear force; and pulverizing particles and then dispersing the same in liquid.

A high-pressure spray disperser is a system capable of colliding and crushing particles by spraying the dispersion in a high pressure.

An ultrasonic wave disperser may disperse particles using an ultrasonic wave, which may include directly contacting an ultrasonic wave homogenizer or disposing the same outside of the vessel.

Crushing the fullerene may be performed until an average particle size of the fullerene becomes less than or equal to about 100 nm, and for example, may be performed for less than or equal to about 100 hours, for about 1 hour to about 100 hours, or for about 10 hours to about 100 hours.

The agglomerated fullerene which is dispersed in water by the crushing may be pulverized to provide a plurality of fullerene particles, and the pulverized fullerene particles may have an average particle diameter of less than or equal to about 100 nm, for example, about 30 nm to about 100 nm. The pulverized fullerene particles may include a low-value hydroxyl fullerene in which a part of the surface is substituted with hydroxy groups, for example, the pulverized fullerene particles may include a low value hydroxyl fullerene (intermediate of hydroxyl fullerene) represented by Cₓ(OH)_{y} (wherein, x is 60, 70, 74, 76, or 78, and y is 6 to 12).

Subsequently, the pulverized fullerene is oxidized. For example, the oxidation may include adding a second oxidizing agent to the pulverized fullerene and heating the same.

The second oxidizing agent may be for example a material capable of producing a hydroxide radical and may be for example hydrogen peroxide, hydrogen peroxide water, ozone, or a combination thereof. The second oxidizing agent may be the same as or different from the first oxidizing agent. The second oxidizing agent may be included more than the pulverized fullerene, for example, the second oxidizing agent may be included in an amount of about 200 parts by weight to about 2000 parts by weight based on 100 parts by weight of the pulverized fullerene.

The heat-treating may be performed at a temperature of greater than or equal to the room temperature, for example, at a temperature of about 30° C. to about 150° C., for example about 50° C. to about 120° C. The heat-treating may be performed until the average particle size of the pulverized fullerene particles becomes less than or equal to about 10 nm, for example, and may be performed for less than or equal to about 100 hours, or for about 10 hours to about 100 hours.

Hydroxyl fullerene as used herein refers to a population of hydroxyl fullerenes having an average number of hydroxyl groups y, and represented by Cₓ(OH)_{y} (wherein, x is 60, 70, 74, 76 or 78 and y is 12 to 44) may be obtained by oxidizing the pulverized fullerene. The hydroxyl fullerene may be for example represented by Cₓ(OH)_{y} (wherein, x is 60, 70, 74, 76, or 78 and y is 24 to 44), for example Cₓ(OH)_{y} (wherein, x is 60, 70, 74, 76, or 78 and y is 30 to 44), for example Cₓ(OH)_{y} (wherein, x is 60, 70, 74, 76, or 78 and y is 32 to 44), for example Cₓ(OH)_{y} (wherein, x is 60, 70, 74, 76, or 78 and y is 36 to 44). The average number of hydroxy groups in the hydroxyl fullerene may be measured by, for example, an atomic analysis, a thermogravimetric analysis, a spectrophotometric analysis, or a mass analysis, and the like. For example, the average number of hydroxy groups in the hydroxyl fullerene may be an average of two highest peaks in the liquid chromatography mass spectrum (LCMS).

The hydroxyl fullerene may have a particle diameter of, for example, less than or equal to about 10 nm, less than or equal to about 5 nm, less than or equal to about 3 nm, less than or equal to about 2 nm, or less than or equal to about 1 nm. The hydroxyl fullerene may have a particle diameter of, for example, about 0.1 nm to about 10 nm, about 0.1 nm to about 5 nm, about 0.1 nm to 3 nm, about 0.1 nm to about 2 nm, or about 0.1 nm to about 1 nm.

The hydroxyl fullerene may be effectively dispersed in water.

According to the method, a hydroxyl fullerene dispersion in which hydroxyl fullerene represented by Cₓ(OH)_{y} (wherein, x is 60, 70, 74, 76, or 78 and y is 12 to 44) is dispersed in water may be obtained.

The hydroxyl fullerene dispersion may be obtained by a one-pot process which may not include a solvent exchange in the process as described above, and may use only water as a solvent, and may not use an organic solvent such as toluene, benzene, or a combination thereof. Thus the solvent exchanging and the washing processes may not be included, and the hydroxyl fullerene dispersion may be obtained in a simple process.

The hydroxyl fullerene dispersion may be used as a polishing slurry.

The obtained hydroxyl fullerene, which is a particle having a high hardness, may effectively function as an abrasive in the polishing slurry and may be effectively employed for, e.g., on, a fine pitch structure having a width of less than or equal to about 10 nm, by having a very small particle diameter of, for example, less than or equal to about 10 nm, unlike an abrasive particle having a particle diameter of tens to hundreds of nanometers such as silica. Thus, the polishing slurry including the hydroxyl fullerene may reduce a damage to or shape deformation, such as scratch, dishing, erosion, or a combination thereof, of a structure to be polished.

The polishing slurry may further include an additive in addition to the hydroxyl fullerene dispersion and the additive may be for example a chelating agent, an oxidizing agent, a surfactant, a dispersing agent, a pH controlling agent, or a combination thereof, but is not limited thereto.

The chelating agent may be for example phosphoric acid, nitric acid, citric acid, malonic acid, a salt thereof, or a combination thereof, but is not limited thereto.

The oxidizing agent may be for example hydrogen peroxide, sodium hydroxide, potassium hydroxide, or a combination thereof, but is not limited thereto.

The surfactant may be an ionic or non-ionic surfactant, for example a copolymer of ethylene oxide, a copolymer of propylene oxide, an amine compound, or a combination thereof, but is not limited thereto.

The dispersing agent promotes uniform dispersion of a composite including the hydrophilic fullerene and the ionic compounds and increases polishing efficiency or a polishing speed and may be for example selected from poly(meth)acrylic acid, poly(meth)acryl-maleic acid, polyacrylonitrile-co-butadiene-acrylic acid, carboxylic acid, sulfonic ester, sulfonic acid, phosphoric ester, cellulose, diol, a salt thereof, or a combination thereof, but is not limited thereto.

The pH controlling agent may control pH of the polishing slurry and may be for example inorganic acid, organic acid, a salt thereof, or a combination thereof. The inorganic acid may include for example nitric acid, hydrochloric acid, phosphoric acid, sulfuric acid, hydrofluoric acid, bromic acid, iodic acid or a salt thereof, the organic acid may include for example formic acid, malonic acid, maleic acid, oxalic acid, adipic acid, citric acid, acetic acid, propionic acid, fumaric acid, lactic acid, salicylic acid, benzoic acid, succinic acid, phthalic acid, butyric acid, glutaric acid, glutamic acid, glycolic acid, lactic acid, aspartic acid, tartaric acid, or a salt thereof, but is not limited thereto.

Each additive may be independently included in a trace amount of, for example, about 1 parts per million (ppm) to 100,000 ppm, but is not limited thereto.

The polishing slurry may be employed for providing various structures, for example, the polishing slurry may be applied for, e.g., in, a polishing process of a conductor such as a metal line or a shallow trench isolation (STI) or a polishing process of an insulator such as an insulation layer.

Hereinafter, a method of manufacturing a semiconductor device using the polishing slurry is exemplified.

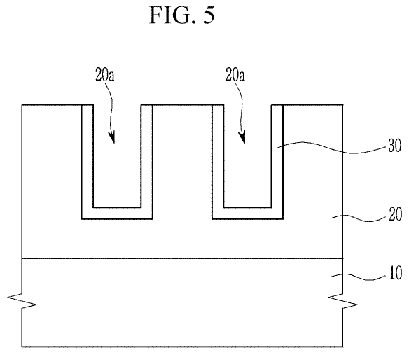

FIGS. 5 to 8 are cross-sectional views sequentially showing a method of manufacturing a semiconductor device according to an embodiment.

As shown in FIG. 5, an interlayer insulating layer 20 is formed on a semiconductor substrate 10. The interlayer insulating layer 20 may include oxide, nitride, oxynitride, or a combination thereof. Subsequently, the interlayer insulating layer 20 is etched to provide a trench 20a. The trench 20a may have a width of less than or equal to about 10 nm. Subsequently, a barrier layer 30 is formed on the wall surface of the trench 20a. The barrier layer 30 may include, for example, Ta, TaN, or a combination thereof, but is not limited thereto.

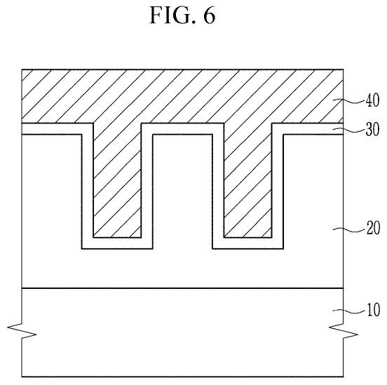

As shown in FIG. 6, a metal such as copper (Cu) is filled in the trench to provide a metal layer 40.

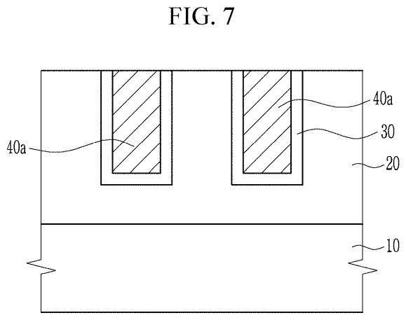

As shown in FIG. 7, a surface of each of the metal layer 40 and the barrier layer 30 is planarized to correspond to a level of the surface of the interlayer insulating layer 20 and filled to provide a filled metal layer 40a. The planarization may be performed by a chemical mechanical polishing (CMP) process, and may use the polishing slurry including the hydroxyl fullerene dispersion. For example, when the barrier layer 30 is a Ta layer, and the metal layer 40 is a Cu layer, it may be desirable that a polishing selectivity of Ta to Cu of the polishing slurry be relatively high, for example, it may be desirable that a polishing selectivity of Ta to Cu of the polishing slurry is greater than about 50:1.

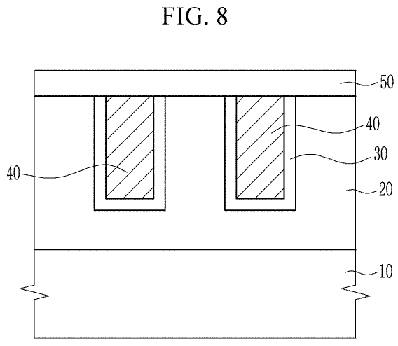

As shown in FIG. 8, a capping layer 50 is formed on the filled metal layer 40a, the barrier layer, and the interlayer insulating layer 20. The capping layer 50 may include SiN, SiC, or a combination thereof, but is not limited thereto.

So far, the method of manufacturing a semiconductor device according to an embodiment has been described, but it is not limited thereto, and it may be employed for providing a semiconductor device having various structures.

Hereinafter, the embodiments are illustrated in more detail with reference to examples. However, these embodiments are exemplary, and the present disclosure is not limited thereto.

### Preparation Example I

### Preparation Example 1

Beads are filled in ⅓ a volume of a beads-mill vessel having a height of about 100 millimeters (mm) and a diameter of about 50 mm and added with 1 gram (g) of fullerene (C60, Nanom purple ST, Frontier Carbon), 3 grams per liter (g/L) of a dispersing agent (polyacrylic acid, Mw 1800, Merck), and 100 g of water. Beads includes 50 g of zirconia beads having an average particle diameter of 500 micrometers (μm), 50 g of zirconia beads having an average particle diameter of 5 mm, and 50 g of zirconia beads having an average particle diameter of 10 mm.

Subsequently, the vessel is rotated for 40 hours, and the sample is taken out to measure a particle diameter. The particle diameter is measured using a Zeta-Potential & Particle Size Analyzer ELS-Z (Otsuka Electron) which is a dynamic light scattering particle size analyzer.

Subsequently, after monitoring that the sample has a particle diameter of less than or equal to 100 nanometers (nm), 100 g of 30 weight percent (wt %) hydrogen peroxide is added thereto to remove beads. Subsequently, the sample is agitated at about 70° C. for 8 days to prepare dispersion.

### Preparation Example 2

Dispersion is prepared in accordance with the same procedure as in Preparation Example 1, except using 1 g/L of a dispersing agent (polyacrylic acid).

### Preparation Example 3

Dispersion is prepared in accordance with the same procedure as in Preparation Example 1, except that 0.5 g/L of a dispersing agent (polyacrylic acid) is used, and the vessel is rotated for 90 hours.

### Preparation Example 4

Dispersion is prepared in accordance with the same procedure as in Preparation Example 1, except that 0.25 g/L of a dispersing agent (polyacrylic acid) is used, and the vessel is rotated for 90 hours.

### Preparation Example 5

Dispersion is prepared in accordance with the same procedure as in Preparation Example 1, except that 3 g/L of a dispersing agent (Copper(II) Acetate) is used, and the vessel is rotated for 80 hours.

### Preparation Example 6

Dispersion is prepared in accordance with the same procedure as in Preparation Example 1, except that 1 g/L of a dispersing agent (ethylene glycol) is used instead of the dispersing agent (polyacrylic acid).

### Preparation Example 7

Dispersion is prepared in accordance with the same procedure as in Preparation Example 1, except that 1 g/L of a dispersing agent (polyethylene glycol, Mw 200) is used instead of a dispersing agent (polyacrylic acid).

### Preparation Example 8

A dispersion is prepared in accordance with the same procedure as in Preparation Example 1, except that 30 wt % of hydrogen peroxide is used without using the dispersing agent.

### Comparative Preparation Example 1

A dispersion is prepared in accordance with the same procedure as in Preparation Example 1, except that the dispersing agent (polyacrylic acid) is not used.

### Preparation Example II

### Preparation Example 9

0.25 g of fullerene (C60) (Nanom purple ST, Frontier Carbon), 0.1 wt % of a dispersing agent 1 (ethylene glycol), 0.1 wt % of a dispersing agent 2 (polyacrylic acid, Mw 18,000), and 250 g of water are added into a vessel of a high-speed shearing type agitator (FM-80-5-, Primix)

Subsequently, the vessel is rotated for 40 hours, and the sample is taken out to measure a particle diameter. The particle diameter is measured using a Zeta-Potential & Particle Size Analyzer ELS-Z (Otsuka Electron) which is dynamic light scattering-type particle size distribution measurer.

Subsequently, after monitoring that the sample has a particle diameter of less than or equal to 100 nm, 250 g of 30 wt % hydrogen peroxide is added thereto. Subsequently, the sample is agitated at about 70° C. for 8 days to prepare dispersion.

### Preparation Example 10

A dispersion is prepared in accordance with the same procedure as in Preparation Example 9, except that it further includes 6 wt % of hydrogen peroxide in the vessel besides the fullerene, the dispersing agents 1, 2, and water.

### Preparation Example 11

A dispersion is prepared in accordance with the same procedure as in Preparation Example 9, except that it further includes 30 wt % of hydrogen peroxide in the vessel besides the fullerene, the dispersing agents 1, 2, and water.

### Preparation Example 12

A dispersion is prepared in accordance with the same procedure as in Preparation Example 9, except that the dispersing agent 2 is not used, but 6 wt % of hydrogen peroxide is included.

### Preparation Example 13

A dispersion is prepared in accordance with the same procedure as in Preparation Example 9, except that the dispersing agents 1 and 2 are not used, but 6 wt % of hydrogen peroxide is included.

### Comparative Preparation Example 2

A dispersion is prepared in accordance with the same procedure as in Preparation Example 9, except that the dispersing agents 1 and 2 are not used.

### Evaluation I

Each dispersion obtained from Preparation Example 1 and Comparative Preparation Example 1 is analyzed using a liquid chromatography mass spectrometry (LCMS).

LCMS is evaluated using LTQ Orbitap XL (Thermo Fisher Scientific).

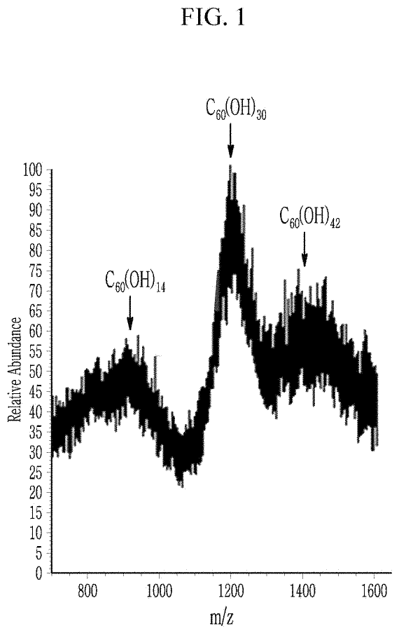

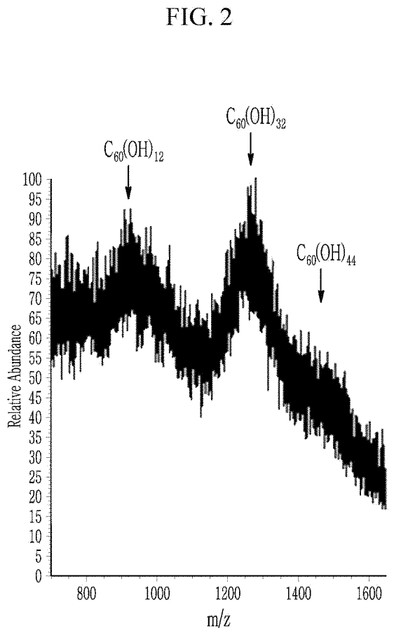

The results are shown in FIGS. 1 and 2.

FIG. 1 is a LCMS graph of hydroxyl fullerene included in the dispersion obtained from Preparation Example 1; and FIG. 2 is a LCMS graph of hydroxyl fullerene included in the dispersion obtained from Comparative Preparation Example 1.

Referring to FIGS. 1 and 2, it is confirmed that the dispersion obtained from Preparation Example 1 includes mostly hydroxyl fullerene having 30 hydroxy groups and hydroxyl fullerene having 42 hydroxyl groups; on the other hand, the dispersion obtained from Comparative Preparation Example 1 includes mostly hydroxyl fullerene having 12 hydroxy groups and hydroxyl fullerene having 32 hydroxy groups. The average number of hydroxyl groups of the hydroxyl fullerene included in the dispersion may be obtained by an average of two highest peaks in mass spectrum of the hydroxyl fullerene. The dispersion obtained from Preparation Example 1 includes a hydroxyl fullerene having an average number of hydroxy groups of 36, and the dispersion obtained from Comparative Preparation Example 1 includes hydroxyl fullerene of an average number of hydroxy groups of 22.

### Evaluation II

Each dispersion obtained from Preparation Examples 1 to 8 and Comparative Preparation Example 1 is evaluated for a particle diameter of the hydroxyl fullerene particle and the number of hydroxy groups.

The particle diameter is measured using a dynamic scattering particle diameter dispersion measurer (Zeta-Potential & Particle Size Analyzer ELS-Z).

The average number of hydroxy groups is evaluated by a Fourier transform infrared spectroscopy (FTIR).

The results are shown in Table 1.

TABLE 1

| | Average particle | Average number of |
|---|---|---|
| | diameter (nm) | hydroxy group * |
| Preparation Example 1 | 1.4 | 36 |
| Preparation Example 2 | 1.3 | 36 |
| Preparation Example 3 | 2.5 | 34 |
| Preparation Example 4 | 3.7 | 28 |
| Preparation Example 5 | 1.9 | 35 |
| Preparation Example 6 | 1.4 | 36 |
| Preparation Example 7 | 1.5 | 36 |
| Preparation Example 8 | 1.4 | 36 |
| Comparative Preparation | 24 | 22 |
| Example 1 | | |

* average number of hydroxy groups is an average of two highest peaks in mass spectrum of the hydroxyl fullerene.

Referring to Table 1, it is confirmed that each dispersion according to Preparation Examples 1 to 8 includes hydroxyl fullerene particles having a very small particle diameter of less than or equal to 10 nm.

### Evaluation III

Each dispersion obtained from Preparation Examples 9 to 13 and Comparative Preparation Example 2 are evaluated for a particle diameter of the hydroxyl fullerene particle and the number of hydroxy groups.

The results are shown in Table 2.

TABLE 2

| | Average particle | Average number of |
|---|---|---|
| | diameter (nm) | hydroxy group * |
| Preparation Example 9 | 2.5 | 30 |
| Preparation Example 10 | 1.4 | 36 |
| Preparation Example 11 | 1.5 | 36 |
| Preparation Example 12 | 1.7 | 35 |
| Preparation Example 13 | 1.6 | 36 |
| Comparative Preparation | >1 μm | 8 |
| Example 2 | | |

* average number of hydroxy groups is an average of two highest peaks in mass spectrum of the hydroxyl fullerene.

Referring to Table 2, it is confirmed that each dispersion according to Preparation Examples 9 to 13 includes hydroxyl fullerene particles having a very small particle diameter of less than or equal to 10 nm.

### Evaluation IV

The color change of the dispersion obtained from Preparation Example 1 is monitored according to a lapse of time.

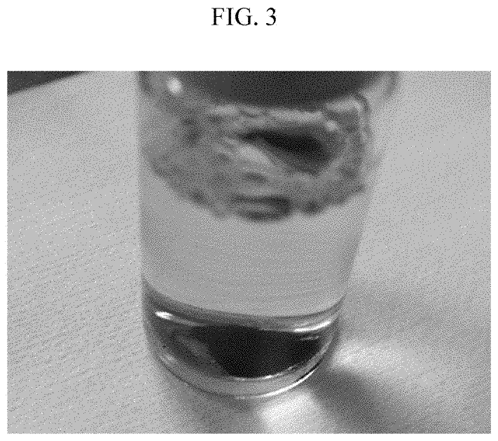

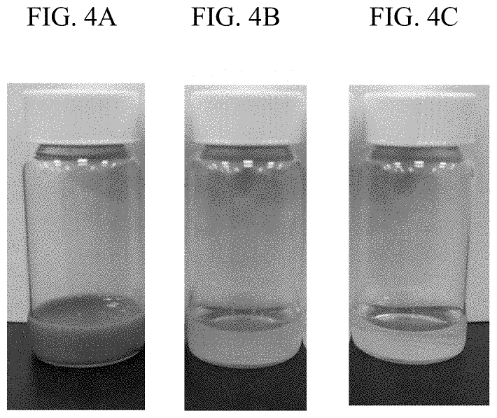

FIG. 3 is a photograph of a fullerene (C60) dispersion before initiating the beads-milling in Preparation Example 1; FIG. 4A is a photograph of the dispersion directly after the beads-milling in Preparation Example 1; FIG. 4B is a photograph of the dispersion after performing an oxidation process for about 4 days; and FIG. 4C is a photograph of the dispersion after performing the oxidation process for 8 days.

Referring to Tables 1 and 2, it is confirmed that after crushing, an average number of hydroxyl groups in the Examples was 0, 12, 24, or 36. Referring to FIG. 3, it is confirmed that fullerene agglomerate in which the fullerene is agglomerated precipitated and was not dispersed before initiating the beads milling, and on the other hand, referring to FIG. 4A, FIG. 4B, and FIG. 4C, it is confirmed that the dispersion changed to have a brighter color as the average number of hydroxyl groups of the fullerene is increased, and the fullerene is dispersed, e.g., the dispersion becomes more transparent by inspection by the naked eye.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

What is claimed is:

1. A method of preparing hydroxyl fullerene dispersion, the method comprising
combining
fullerene,
a dispersing agent, a first oxidizing agent, or a combination thereof, and
water
to provide a mixture,
crushing the mixture to obtain pulverized fullerene, and
oxidizing the pulverized fullerene to obtain hydroxyl fullerene represented by Cₓ(OH)_{y} wherein, x is 60, 70, 74, 76 or 78 and y is 12 to 44, and to provide the hydroxyl fullerene dispersion.

2. The method of claim 1, wherein the oxidizing of the pulverized fullerene comprises adding a second oxidizing agent to the pulverized fullerene to provide a second mixture comprising the second oxidizing agent, and heat-treating the second mixture.

3. The method of claim 2, wherein the first oxidizing agent and the second oxidizing agent are the same or different materials capable of producing a hydroxide radical.

4. The method of claim 2, wherein the first oxidizing agent and the second oxidizing agent independently comprise hydrogen peroxide, hydrogen peroxide water, ozone, or a combination thereof.

5. The method of claim 2, wherein the heat-treating is performed at about 50° C. to about 120° C.

6. The method of claim 1, wherein the dispersing agent comprises a water-soluble monomer, a water-soluble oligomer, a water-soluble polymer, a metal salt, or a combination thereof.

7. The method of claim 1, wherein crushing of the mixture is performed using a beads mill, a high-speed rotation agitator, a vacuum emulsion agitator, a colloid mill, a roll mill, a high-pressure spraying disperser, or an ultrasonic wave disperser.

8. The method of claim 1, wherein the crushing of the mixture is performed for about 1 hour to about 100 hours.

9. The method of claim 1, wherein
the dispersing agent is present in an amount of greater than 0 weight percent to about 10 weight percent based on a total amount of the mixture,
the first oxidizing agent is present in an amount of greater than 0 weight percent to about 30 weight percent based on a total amount of the mixture.

10. The method of claim 1, wherein the pulverized fullerene comprises a plurality of pulverized fullerenes and an average particle diameter of the plurality of pulverized fullerenes is less than or equal to about 100 nanometers.

11. The method of claim 1, wherein the hydroxyl fullerene comprises a plurality of hydroxyl fullerenes and an average particle diameter of the plurality of hydroxyl fullerenes is less than or equal to about 10 nanometers.

12. The method of claim 1, wherein an organic solvent is not used.

13. The method of claim 1, wherein the hydroxyl fullerene is represented by Cₓ(OH)_{y} wherein, x is 60, 70, 74, 76, or 78 and y is 24 to 44.

14. A hydroxyl fullerene dispersion obtained by the method of claim 1.

15. A polishing slurry comprising the hydroxyl fullerene dispersion of claim 14.

16. A polishing slurry comprising
hydroxyl fullerene represented by Cₓ(OH)_{y} wherein, x is 60, 70, 74, 76 or 78 and y is 12 to 44, and having an average particle diameter of less than or equal to about 10 nanometers, and
water.

17. The polishing slurry of claim 16, wherein the polishing slurry is more transparent by inspection by the naked eye than water and fullerene represented by formula Cₓ wherein, x is 60, 70, 74, 76, or 78.

18. The polishing slurry of claim 16, wherein the hydroxyl fullerene is represented by Cₓ(OH)_{y} wherein, x is 60, 70, 74, 76, or 78 and y is 24 to 44.

19. The polishing slurry of claim 16, further comprising a chelating agent, a surfactant, or a combination thereof.

20. A method of manufacturing a semiconductor device, the method comprising polishing a surface of the semiconductor device using the polishing slurry of claim 16.

21. A method of polishing a semiconductor device, the method comprising
manufacturing a polishing slurry, the method comprising
combining fullerene, a dispersing agent, a first oxidizing agent, or a combination thereof, and water to provide a mixture,
crushing the fullerene to obtain pulverized fullerene, and
oxidizing the pulverized fullerene to obtain hydroxyl fullerene represented by Cₓ(OH)_{y}, wherein x is 60, 70, 74, 76 or 78 and y is 12 to 44, and to prepare the hydroxyl fullerene dispersion; and
polishing a surface of the semiconductor device using the polishing slurry.
